(19) United States
(12) Patent Application Publication
(10) Pub. No.: US 2012/0287594 A1
(43) Pub. Date: Nov. 15, 2012

(54) BASE FOR A POINT OF SALE SYSTEM

(75) Inventor: Chun-Shih KO, New Taipei City (TW)

(73) Assignee: PARTNER TECH CORP., New Taipei City (TW)

(21) Appl. No.: 13/185,960

(22) Filed: Jul. 19, 2011

(30) Foreign Application Priority Data
May 11, 2011 (TW) 100208447

(51) Int. Cl. H05K 7/02

(52) U.S. Cl. 361/809

(57) ABSTRACT

A base for a point of sale system includes a baseboard and a first connection base. The point of sale system further comprises a mainframe, which includes one or more connection sockets, a case with a mainframe tenon and a touch panel. The baseboard has a baseboard tenon separably connected to the mainframe tenon. In addition, the first connection base has a first extending position and a first connection position, and the first connection base has a first connection base sliding unit and one or more than one connection plugs. The connection plugs are at the same side of the first connection sliding unit which is opposite to the connection sockets, and the amount of the connection plugs and the connection sockets are the same, and, on the other hand, the relative disposition of the connection plugs and the connection sockets are corresponsive. Further, the first baseboard sliding unit slidably connects to the first connection base sliding unit. As users slide the first connection base from the first extending position to the first connection position, the connection plugs and the connection sockets are electrically connected.

### CROSS-REFERENCES TO RELATED APPLICATIONS

Not applicable.

### BACKGROUND OF THE INVENTION

1. Field of the Invention

The present invention relates to a base for a point of sale system which has a base and a mainframe that are separate, and the base has a first connection base, which is slidable. When the first connection base slides to a first connection position, the first connection base has a connection plug connecting to the mainframe.

2. Descriptions of the Related Art

As technology develops, some restaurants, retailers, hotels or shopping malls gradually abandon traditional cash registers and adopt a point of sale system (POS) as electronic systems for displaying, counting, billing, or reserves tracing. With the use of POS, manufacturers or sellers can readily integrate the needs of each stage in the industry, so as to improve the efficiency of business management.

However, a conventional POS needs to be fixed to a fixture, like a wall or a table. The input devices, such as magnetic strip readers for credit cards or barcode readers, are usually installed directly on conventional POS, and the POS often connects to the Internet via wired network, so that conventional POS has difficulties being relocated and is inconvenient to be portable.

In addition, some conventional wireless POS connect to the Internet via a wireless network, nevertheless, because the user often carries the POS to move around, and because there is no fixed devices to accommodate the POS, the user often forgets where the POS is placed. If conventional POS needs to connect to an external device, such as magnetic strip readers for credit cards or barcode readers, the user has to install the connection wire to each device one by one, and the improper connection between the POS and those external devices might occur easily. As such, users often find that such POS is inconvenient to be used, and those connection wires are often messy and easy to knot with each other.

Furthermore, even if a conventional POS has a separable base and mainframe, but the space of the base to accommodate the mainframe is fixed and it is difficult to adjust the space to accommodate the mainframe with a different size. Hence, once users replace the mainframe with a different size, the base should be replaced as well.

### SUMMARY OF THE INVENTION

To attain the above objective, the first aspect of the present invention provides a base for a POS, and the POS further comprises a mainframe. The base has a baseboard and a first connection base, and the baseboard and the first connection base are slidably connected. The baseboard has a baseboard tenon and a first baseboard sliding unit, wherein the baseboard tenon can operatively connect to the mainframe tenon. When the first connection base slides from a first extending position to a first connection position, connection plugs on the first connection base and connection sockets on the mainframe have electrical connection.

The primary objective of this invention is to provide a base for a POS, the POS further comprises a mainframe, which includes one or more connection sockets, a case with a mainframe tenon and a touch panel, and the touch panel is in the middle of the case. The connection socket is at one side of the case which is opposite to and electrically connected with the base.

Another objective of this invention is to provide a base for a POS, which has a first connection base, and the first connection base comprises a first connection base sliding unit, and one or more connection plugs. The first connection base has a first connection position where the connection plugs and connection sockets can be electrically connected, and a first extending position where the connection plugs and connection sockets do not electrically connect. The connection plugs are set at the same side of the first connection base which is opposite to and electrically connected with the connection sockets, and the amount of the connection plugs and the connection sockets are the same, and the relative disposition of the connection plugs and the connection sockets are corresponsive. Furthermore, the first baseboard sliding unit and the first connection base sliding unit are slidably connected. Therefore, when the first connection base slides from a first extending position to the first connection position, the connection sockets of the mainframe can attain electrical connection with connection plugs of the first connection base at the same time. When the first connection base slides from the first connection position to the first extending position, the connection sockets of the mainframe will no longer be electrically connected to the connection plugs of the first connection base at the same time. Hence, even if the POS has multiple connection plugs and connection sockets of the same amount, those multiple connection plugs and corresponsive connection sockets will be electrically connected to each other due to the first connection base's one sliding movement, and the connection of connection sockets and connection plugs will improve the stability of the mainframe because the base and the mainframe will not be separated by a slight shake.

Further, the baseboard may comprise of a trough for the mainframe to be placed in. As the mainframe tenon and the baseboard tenon are connected, the mainframe is placed in the trough vertically, so that the mainframe will not be separated from the baseboard because of a slight vertical shake. If the power supply plug is one of the connection plugs, the power supply plug will have electrical connection with the connection sockets when connected, and it will provide power to the mainframe for operation, or electrify the mainframe.

Yet a further objective of this invention is to provide a base for a POS that further comprises a second connection base, and a second baseboard sliding unit on the side of the baseboard that is vertical to the first connection base. The second connection base has a second connection base sliding unit, which is slidably connected to the second baseboard sliding unit. The second connection base further has a second connection position, at which the second connection base contact with the mainframe, and a second extending position at which the second connection base is separated from the mainframe. Because the second connection base can be adjusted to its relative location to the baseboard depending on the size of the mainframe, users only need one base with the second connection base, so that mainframes of different size will fit the base. That is to say, users do not have to buy a new base to fit a new mainframe of a different size than the original one.

Yet a further objective of this invention is to provide a base for a POS with a first connection base, and the connection base has a bulge, when the mainframe tenons connect to the baseboard tenons, and the first connection board is at the first connection position, the bulge and the baseboard will contact to the upper and lower sides of the mainframe separately, so that the bulge and the baseboard hold the mainframe together and make the mainframe hard to separate from the base.

Yet a further objective of this invention is to provide a base for a POS, and the first connection sliding unit and the second connection sliding unit can separately be one of a slideway and a roller device.

Yet a further objective of this invention is to provide a POS which comprises of a mainframe, a baseboard and a first connection base. The mainframe includes one or more connection sockets, a case with a mainframe tenon, and a touch panel. The touch panel is in the middle of the case, and the connection sockets are in the side of the case which is opposite to and electrically connected with the first connection base. The baseboard has a first baseboard sliding unit and a baseboard tenon, which can connect with or separate from the mainframe tenon. The first connection base has a first connection base sliding unit, and one or more connection plugs. If the first connection base has a plurality of connection plugs, the connection plugs are set at the same side of the first connection base which is opposite to and electrically connected with the connection sockets. Besides, the amount of the connection plugs and the connection sockets are the same; on the other way the relative disposition of the connection plugs and the connection sockets are corresponsive. In addition, the first connection base has a first connection position where the connection plugs and the connection sockets have electrical connection, and a first extending position where the connection plugs and the connection sockets do not have electrical connection. The first baseboard sliding unit and the first connection base sliding unit are slidably connected, and when the first connection base slides from the first extending position to the first connection position, the connection sockets and the connection plugs are electrically connected.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a multiple view of a mainframe;

FIG. 2 is a perspective assembly view of an embodiment;

FIG. 3 is an exploded view of an embodiment;

FIG. 4 is a perspective assembly view of another embodiment;

FIG. 5A is a perspective assembly view of a base in combination with a mainframe; and

FIG. 5B is another perspective assembly view of a base in combination with a mainframe.

### DESCRIPTION OF THE PREFERRED EMBODIMENT

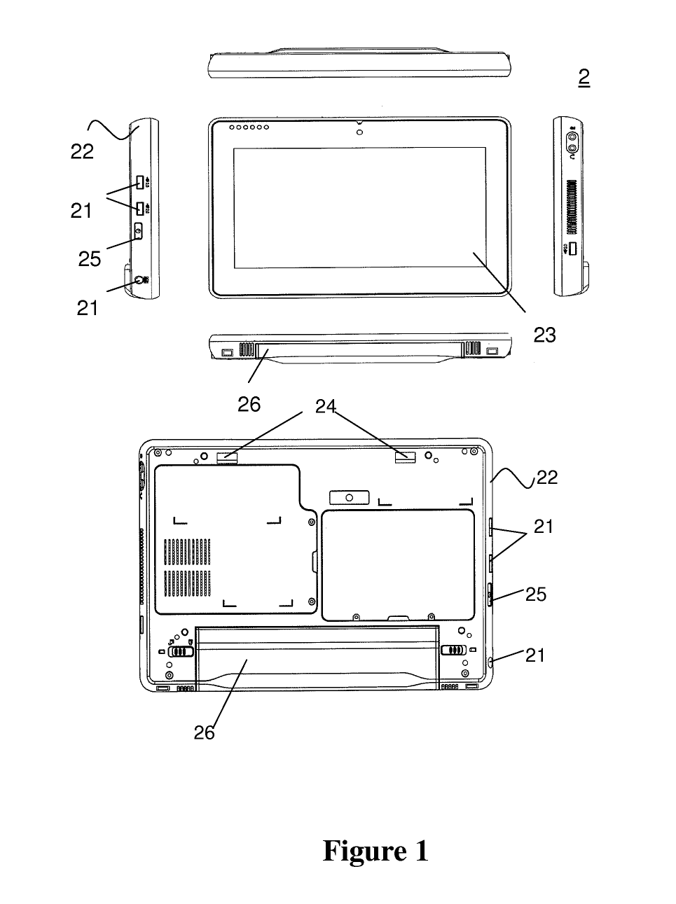

FIG. 1 shows a mainframe 2 of a POS 7. The mainframe has a touch panel 23 in the middle of a case 22, and one or more connection sockets 21 at one side of the case 22 which is opposite to and electrically connected with a base 1. The mainframe 2 may have other connection ports at the sides of the case 22 other than the side with connection sockets 21 which can be connected to connection plugs 42 of a base 1, so that users can use those connection ports to electrically connect with external modules (for example, external monitors, printers, magnetic stripe readers for credit card or barcode readers) other than those set in the base. In better embodiments, the mainframe 2 has a power switch 25 and a rechargeable battery 26, so that users can use the power switch 25 to control the operation of the mainframe 2, and the power of the mainframe 2 can be provided by the rechargeable battery 26. In addition, the case 22 of the mainframe 2 has one or more mainframe tenons 24, and, in better embodiments, the mainframe tenons 24 are set up in the lower side of the case 22, which is the one opposite to the side connected with the touch panel 23, in order to avoid horizontal movements of the mainframe 2.

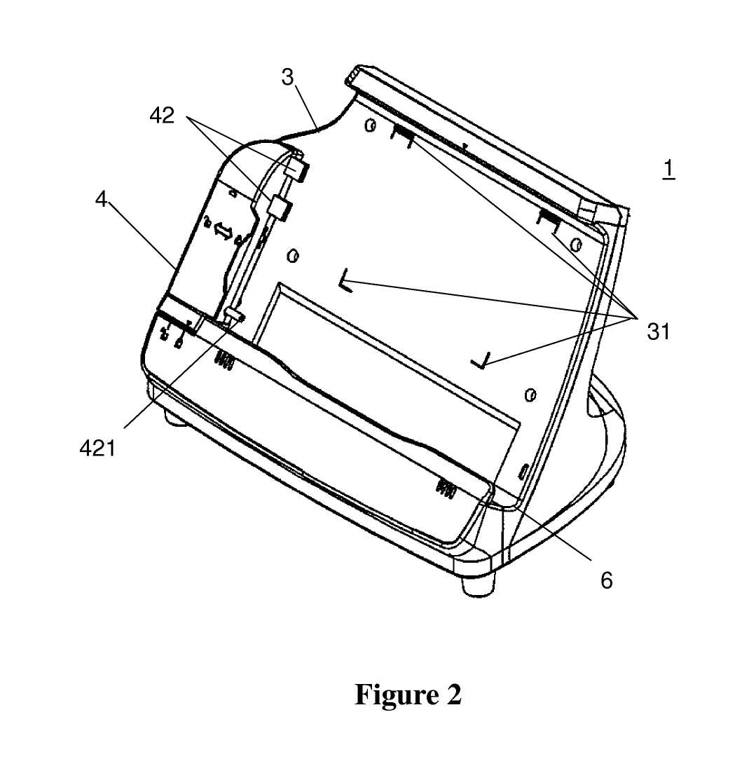

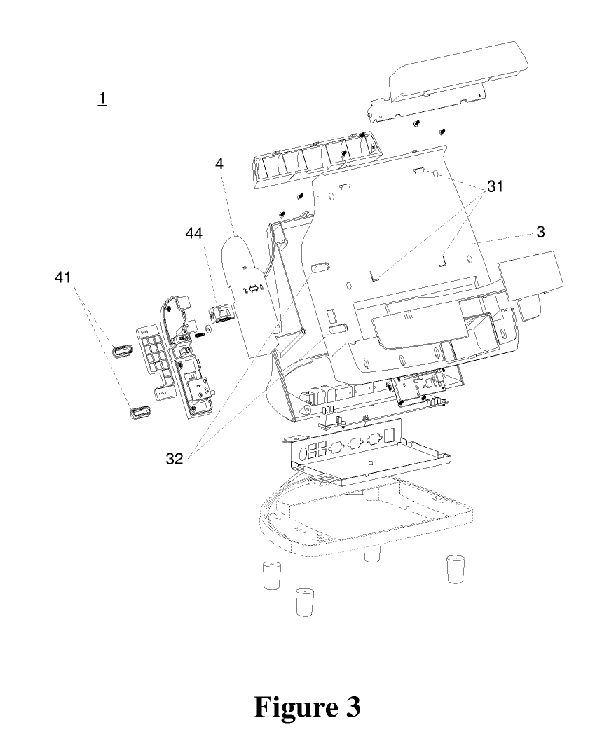

FIG. 2 and FIG. 3 show a base 1 for a POS 7. The base 1 has a baseboard 3 and a first connection base 4. The baseboard 3 has four baseboard tenons 31, which can be operatively connected to the mainframe tenons 24 in FIG. 1, two first baseboard sliding units 32 and a trough 6. When the mainframe 2 and the base 1 are separated, users may carry the mainframe 2 without the base 1 and go to a warehouse to make an inventory check, or introduce products or dishes for customers. Waiters can also show dishes on the touch panel 23 and record what customers order. Furthermore, when the mainframe 2 and the base 1 are electrically connected, the mainframe 2 can be electrified through the power supply plug 421, so that users will be able to connect the mainframe 2 and the base 1 while they stop using the mainframe 2, and avoid the problem of the users forgetting where the mainframe 2 is placed, since the mainframe 2 is so convenient to carry. This results in less difficulties of managing and storing up.

In addition, the trough 6 is designed for the mainframe 2 to be put in vertically. The first connection base 4 has a first connection position where the connection plugs 42 and connection sockets 21 have electrical connection, and a first extending position where the connection plugs 42 and connection sockets 21 do not have electrical connection. As shown in FIG. 3, the first connection base 4 has two first connection base sliding units 41, which slidably connect to the two first baseboard sliding units 32; the first connection base 4 further has three connection plugs 42 (including one power supply plug 421), set in the side of the first connection base 4 which is opposite to the connection sockets 21. Furthermore, the first connection base sliding unit 41 can be one of a slideway and a roller device. As shown in FIG. 3, the first connection base 4 uses two slideways 41 to slide between a first extending position and the first connection position. The amount of the connection plugs 42 (including one power supply plug 421) and that of the connection sockets 21 in FIG. 1 are the same. On the other hand, the relative disposition of the connection plugs 42 and the connection sockets 21 are corresponsive.

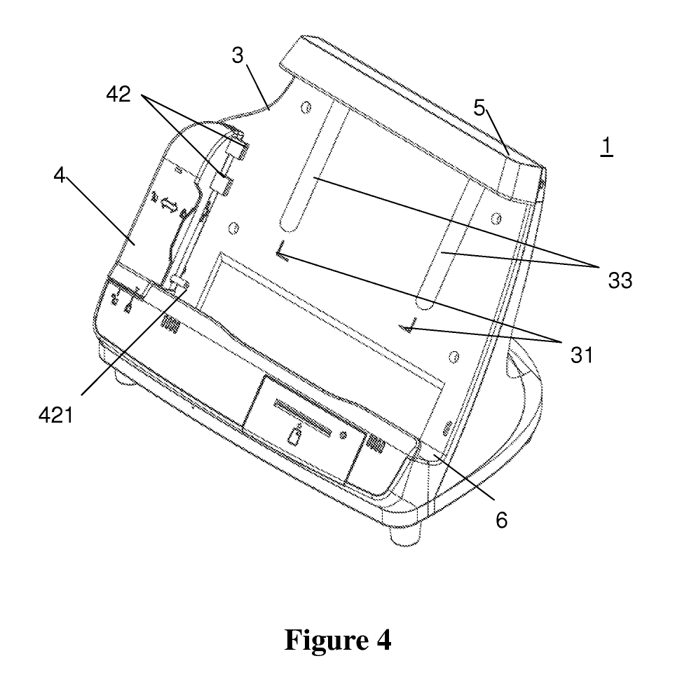

FIG. 4 shows a base for a POS further has a second connection base 5, and a second baseboard sliding unit 33 of the baseboard 3 on the side that is vertical to the first connection base 1. The second connection base 5 further has a second connection position where the second connection base contacts with the mainframe 2, and a second extending position where the second connection base 5 is separate from the mainframe 2. The second connection base 5 further has a second connection base sliding unit 51, which can be one of a slideway and a roller device. The second connection base sliding unit 51 and the second baseboard sliding unit 33 are slidably connected. As shown in FIG. 4, the base 1 has two second baseboard sliding units 33 and two second connection base sliding units 51, and the second connection base sliding units 51 use slideways to let the second connection base 5 slide between a second extending position and the second connection position. Hence, users may adjust the location of the second connection base 5 to a suitable position to match the size of their mainframe 2, and they do not need to buy multiple bases 1 to fit mainframes 2 of a different size.

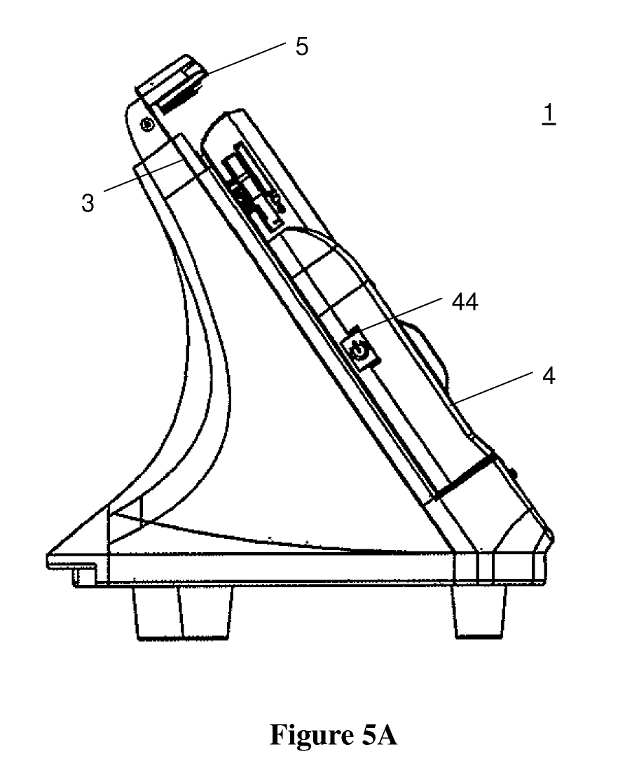

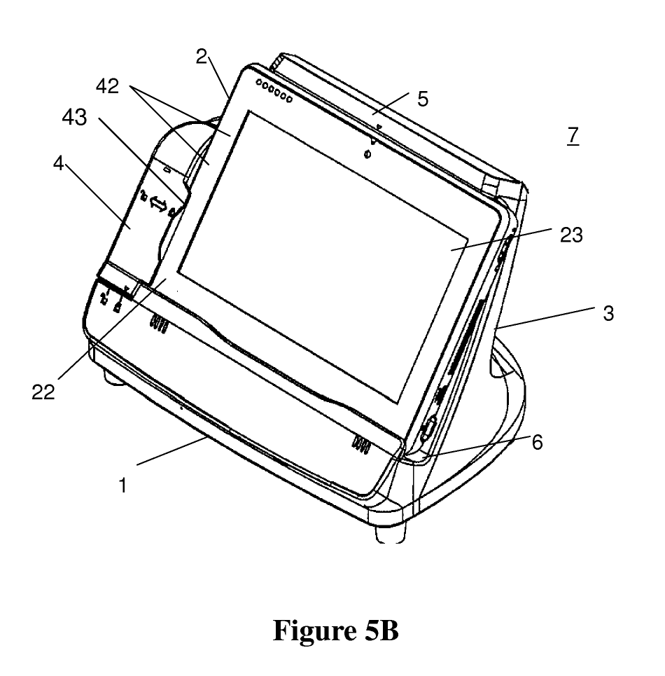

FIGS. 5A and 5B show a POS 7, which has a base 1 and a mainframe 2. As shown in FIG. 5B, the first connection base 4 slides from a first extending position to the first connection position, so the connection sockets 21 and connection plugs 42 have electrical connection. Furthermore, if the connection plugs 42 include a power supply plug 421, the power supply plug 421 can have electrical connection to one of the connection sockets 21 in FIG. 1, so that power of the base 1 may be transmitted to the mainframe 2 through the power supply plug 421 and a corresponsive connection socket 21 and the rechargeable battery 26 of the mainframe 2 may be electrified.

Therefore, users may use the mainframe 2 separate from the base 1 for a period time till the rechargeable battery 26 is out of power. On the other hand, when users use the mainframe 2 with the base 1 connected or when users do not need to use the mainframe 2 and connect the mainframe 2 and the base 1, users may slide the first connection base 4 to the first connection position (shown in FIG. 5A), and the base 1 will transmit power to the mainframe 2 through the power supply plug 421 and the corresponsive connection socket 21 to provide necessary power to the mainframe 2 and electrify the rechargeable battery 26.

In addition, the first connection base 4 may have a bulge 43. As the mainframe tenons 24 and the baseboard tenons 31 are connected, and when the first connection base 4 is at the first connection position, the bulge 43 and the baseboard 3 contact the upper and lower sides of the case 22 of the mainframe 2 separately, so that the bulge 43 and the baseboard 3 hold the mainframe 2 together and make the mainframe 2 hard to separate from the base 1 under slight shake.

Furthermore, the second connection base 5 slides from a second extending position (as shown in FIG. 5A) to the second connection position (as shown in FIG. 5B), so that the second connection base 5 contacts with the mainframe 2. When users replace the mainframe 2 in FIG. 5B with a smaller mainframe 2, the second connection base 5 should slide downward to another new and suitable second connection position to make the second connection base 5 contact with the smaller mainframe 2.

Please refer to FIG. 5A and FIG. 3 together, when users press a base power button 44, the base power button 44 will push the power switch 25 of the mainframe 2 in FIG. 1. Hence, when users use the mainframe 2 with the base 1 connected, they can use the base power button 44 to press the power switch 25 to turn on the mainframe 2 directly without separating the mainframe 2 and the base 1 first.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A base for a point of sale system, the point of sale system comprising a mainframe, which includes one or more connection sockets, a touch panel and a case with a mainframe tenon, wherein the touch panel is disposed in the middle of the case, the connection sockets being disposed at a side of the case to be opposite to and electrically connected with the base, the base comprising:
a baseboard, having a baseboard tenon and a first baseboard sliding unit, wherein the baseboard tenon is able to operatively connect with the mainframe tenon; and
a first connection base, having a first connection base sliding unit and one or more connection plugs being disposed at a side of the first connection base to be opposite to and electrically connected with the connection sockets, the connection plugs and the connection sockets having equal amounts and being arranged correspondingly, wherein the first connection base is at a first connection position where the connection plugs and the connection sockets are electrically connected, and is at a first extending position where the connection plugs and the connection sockets are electrically disconnected;
wherein the first baseboard sliding unit is slidably connected with the first connection base sliding unit, so that the connection sockets and the connection plugs are electrically connected when the first connection base slides from the first extending position to the first connection position.

2. The base for a point of sale system of claim 1, wherein the base includes a trough for accommodating the mainframe vertically when the mainframe tenon is connected with the baseboard tenon.

3. The base for a point of sale system of claim 1, wherein the connection plugs include a power supply plug.

4. The base for a point of sale system of claim 2, wherein the baseboard includes a second baseboard sliding unit disposed at a side of the baseboard being perpendicular to the first connection base, and the base includes a second connection base, which has a second connection base sliding unit slidably connected to the second baseboard sliding unit, wherein the second connection base is located at a second connection position where the second connection base contacts with the mainframe, and is located at a second extending position where the second connection base is detached from the mainframe.

5. The base for a point of sale system of claim 1, wherein the first connection base includes a bulge, the bulge and the baseboard cooperatively holding the mainframe by contacting the upper and lower sides of the mainframe respectively when the mainframe tenon connects with the baseboard tenon and the first connection base is located at the first connection position.

6. The base for a point of sale system of claim 2, wherein the first connection sliding unit is at least one of a rail device and a roller device.

7. The base for a point of sale system of claim 4, wherein the second connection sliding unit is at least one of a rail device and a roller device.

8. A point of sale system, comprising:
a mainframe, having one or more connection sockets, a touch panel, a case with a mainframe tenon, wherein the touch panel is disposed in the middle of the case;
a baseboard, having a baseboard tenon and a first baseboard sliding unit, wherein the baseboard tenon is able to operatively connect with the mainframe tenon; and
a first connection base, having a first connection base sliding unit and one or more connection plugs being disposed at a side of the first connection base to be opposite to and electrically connected with the connection sockets, the connection plugs and the connection sockets having equal amounts and being arranged correspondingly, wherein the first connection base is at a first connection position where the connection plugs and the connection sockets are electrically connected, and is at a first extending position where the connection plugs and the connection sockets are electrically disconnected;
wherein the first baseboard sliding unit is slidably connected with the first connection base sliding unit, so that the connection sockets and the connection plugs are electrically connected when the first connection base slides from the first extending position to the first connection position.
